(19) United States
(12) Patent Application Publication
(10) Pub. No.: US 2008/0240220 A1
(43) Pub. Date: Oct. 2, 2008

(54) DIGITAL FILTER AND METHOD FOR FILTERING

(75) Inventor: Bjoern ELLERMEYER, Stuttgart (DE)

Correspondence Address: OBLON, SPIVAK, MCCLELLAND MAIER & NEUSTADT, P.C., 1940 DUKE STREET, ALEXANDRIA, VA, 22314, US

(73) Assignee: Sony Deutschland GmbH, Berlin (DE)

(21) Appl. No.: 12/023,377

(22) Filed: Jan. 31, 2008

(30) Foreign Application Priority Data
Mar. 31, 2007 (EP) 07 006 795.4

(51) Int. Cl. H03D 1/00; H04L 27/06

(52) U.S. Cl. 375/232; 375/340

(57) ABSTRACT

Digital filter, comprising a multiplier configured to generate an intermediate signal, wherein said intermediate signal is generated by multiplying an input signal with a filter coefficient signal, wherein said multiplier is operated at a clock rate and said input signal has a sampling rate, wherein said clock rate is higher than said sampling rate; a first buffer configured to supply said filter coefficient signal to said multiplier at said clock rate, wherein said filter coefficient signal represents N filter coefficients in a periodic order, wherein N denotes the order of said digital filter; a second buffer configured to buffer N/2 samples of an intermediate output signal and to generate a respective time delayed intermediate output signal; and an adder configured to generate said intermediate output signal or an output signal of said digital filter based on an addition of said time delayed intermediate output signal and said intermediate signal.

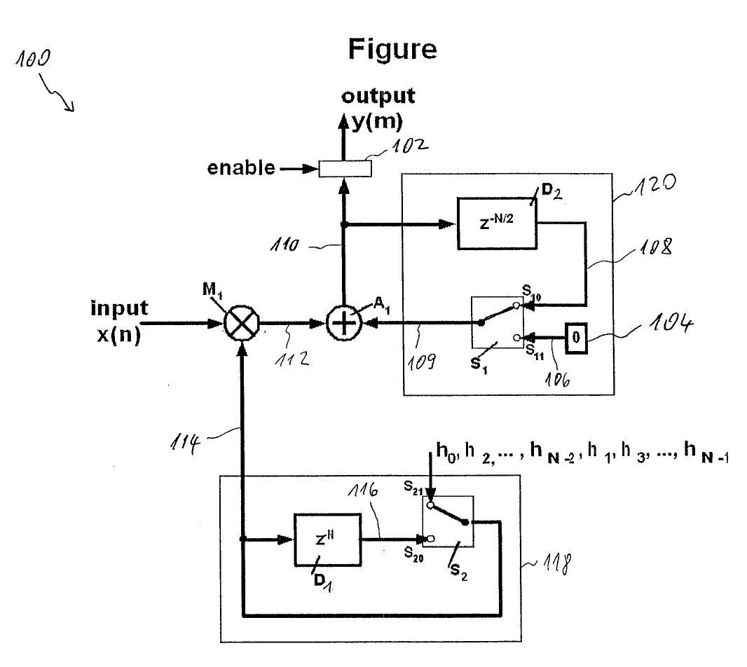

The invention relates to a digital filter and to a method for filtering.

### BACKGROUND

Today, digital filters are widely used.

It is an object of the invention to provide an efficient digital filter that requires a minimum of components and/or hardware requirements.

This object is solved by a digital filter and method for filtering according to claims 1 and 21, respectively.

Further details of the invention will become apparent from a consideration of the drawings and ensuing description.

### BRIEF DESCRIPTION OF THE DRAWINGS

The FIGURE shows a digital filter according to an embodiment of the invention.

### DETAILED DESCRIPTION

In the following, embodiments of the invention are described. It is important to note that all described embodiments in the following may be combined in any way, i.e. there is no limitation that certain described embodiments may not be combined with others.

The FIGURE shows a digital filter 100 comprising a sample and hold unit 102, multiplier M₁, an adder A₁, a first switch S₁, a zero storage 104, a second buffer D₂, a first buffer D₁, and a second switch S₂.

An input signal x(n) may e.g. be a digital signal comprising samples x₀ x₁, x₂, . . .

Input signal x(n) is multiplied with a filter coefficient signal 114 by multiplier M₁. The filter coefficient signal 114 comprises the filter coefficients h₀, h₁, . . . , h_{N} in a predetermined periodical order. In each period of said periodical order, the filter coefficients are arranged in the following order:
h₀, h₂, . . . , h_{N-2}, h₁, h₃, . . . , h_{N-1}.

Thus, in each or at least one period, first all even filter coefficients h₀, h₂, . . . , h_{N-2} occur, and subsequently, all uneven filter coefficients, h₁, h₃, . . . , h_{N-1}.

The filter is operated at a clock rate that is higher than the sampling rate fₛ of input signal x(n). In general, the clock rate should be greater than or equal to

N·fₛ,

wherein N denotes the order of the filter and fₛ denotes the sampling rate of the input signal x(n).

Multiplier M₁ is controlled such that one input sample xᵢ is multiplied with all even filter coefficients h₀, h₂, . . . , h_{N-2}, and that a subsequent input sample xᵢ₊₁ is multiplied with all uneven filter coefficients h₁, h₃, . . . , h_{N-1}. In this example, xᵢ denotes an even input sample, e.g. x₀, x₂, x₄, . . . , and xᵢ₊₁ denotes an uneven input sample, e.g. x₁, x₃, x₅, . . . .

Thus, intermediate signal 112 generated by multiplier M₁ corresponds to products of even filter coefficients h₀, h₂, . . . , h_{N-2} and even input samples x₀, x₂, x₄, . . . and products of uneven filter coefficients h₁, h₃, . . . , h_{N-1} and uneven input samples x₁, x₃, x₅ . . . .

Filter coefficient signal 114 may be determined by any suitable circuit, i.e. it may not be necessary that filter coefficient signal 114 is determined as shown, i.e. based on using the first buffer D₁ and second switch S₂. Any other suitable circuit or method may be used to provide a filter coefficient signal having the above described properties.

However, in the example of the FIGURE, filter coefficient signal 114 is determined by loading the above-mentioned order of the filter coefficients into first buffer D₁ having a size of N. This may e.g. be done during an initialization phase by switching second switch S₂ to position S₂₁ for the first N clock signals of the digital filter. After N cycles of the clock rate, second switch S₂ will be switched to position S₂₀. Thus, after N clock cycles the predetermined order of filter coefficients, h₀, h₂, . . . , h_{N-2}, h₁, h₃, . . . , h_{N-1} is loaded into first buffer D₁ and a periodical order is realized, wherein during each period the above defined predetermined order of filter coefficients is output via filter coefficient signal 114.

The circuit 118 for generating filter coefficient signal 114 may also be referred to as second ring buffer 118.

Intermediate signal 112 is further processed by adder A₁.

Adder A₁ adds said intermediate signal 112 and a first switch output signal 109, which is the output signal of first switch S₁. First switch output signal 109 is equal to a second buffer output signal 108 if first switch S₁ is in position S₁₀. Second buffer output signal 108 is the output signal of second buffer D₂. If first switch S₁ is in position S₁₁, then first switch output signal 109 corresponds to a zero signal 106 provided by zero storage 104.

Second buffer D₂ has a size of N/2 and, thus, second buffer output signal 108 corresponds to a time delayed version of intermediate output signal 110 of adder A₁.

The first switch S₁ is always in position S₁₀ except for each processing of filter coefficient h_{N-1}. In other words, if filter coefficient h_{N-1} is multiplied by multiplier M₁ and the resulting intermediate signal 112 is added by adder A₁, then at this point in time, first switch output signal 109 will be set to zero by switching first switch S₁ to position S₁₁.

Second buffer D₂ and first switch S₁ may be referred to as first ring buffer 120.

Sample and hold unit 102 is controlled to sample and hold intermediate output signal 110, wherein a taking a sample and holding this sample takes place when coefficient h₁ has been multiplied with its corresponding input sample and added with its corresponding sample of first switch output signal 109. In other words, each time filter coefficient h₁ has been multiplied by multiplier M₁ and a corresponding intermediate signal 112 as well as a corresponding intermediate output signal 110 has been generated, the respective sample of intermediate output signal 110 is output as the value for the next output sample of output signal y(m).

Thus, two input samples xᵢ, xᵢ₊₁, result in one output sample, and, therefore, the sampling rate of output signal y(m) is half of the sampling rate of input signal x(n).

First and second buffer D₁, D₂ may be realized e.g. based on a flip flop, RAM, ROM and/or any other suitable storage.

The following gives a further description of the FIGURE:

In digital signal processing sampling rate decimation is often needed to reduce the effort of processing a signal. To decimate a signal by a factor of 2 you must delete the signal components, which lies above 1/2 of the sampling rate of the input signal. After this it is allowed by Shannon's law to delete every 2^{nd} sample.

In digital receivers often FIR filters are used. When these filters have to be realized on an ASIC it is wishful to make them as small as possible to reduce costs. That means that they should be realized with as few elements as possible.

Here a digital FIR filter realization is shown that consists of only one multiplier. The reduction down to only one multiplier is obtained by running the filter with a higher clock rate and changing the coefficient at the multiplier each clock cycle.

The filter is based on only one multiplier to realize an FIR filter of order N. This can be done as the filter runs with a higher clock rate. The clockrate has to be at least N*fₛ (N is the filterorder, fₛ is the sampling rate) to ensure enough time to process all coefficients.

To provide the right samples at the right time two ring buffers 118, 120 are used. The 1^{st} ring buffer 120 contains the product of the signal samples with the filter coefficients, the 2^{nd} ring buffer 118 contains the filter coefficients in the order h₀, h₂, . . . , h_{N-2}, h₁, h₂, . . . , h_{N-1}. This order is loaded with switch setting S₂₁ into the coefficient ring buffer once at start up and then it runs in circle with switch setting S₂₀. The size of the filter coefficient ring buffer 118 is N. The order of the 1^{st} ring buffer 120 is N/2. In case N is odd the size is ceiled to the next integer. The switch setting of S₁ is always S₁₀ except for the calculation of filter coefficient h_{N-1}.

Thus the 1^{st} ring buffer 120 acts as an integrator but has never to be resetted. At startup the content of the 1^{st} ring buffer 120 should be initialized to zero. If the first ring buffer 120 is not initialized properly, only the frirst N/2 output samples may be wrong, i.e. all following samples are output correctly even without any initialization.

The FIGURE shows a block diagram of the filter structure for this filter.

Each input sample must be valid at the multiplyer M₁ to be processed with N/2 filter coeffients. First equal numbered input sample are processed with equal numbered filter coefficients x₀*h₀, x₀*h₂, . . . x₀*h_{N-2}. After this odd numbered input sample are processed with odd numbered filter coefficients x₁*h₁, x₁*h₃, . . . x₁*h_{N-1}. In case N is odd the size of the odd numbered filter coefficients is one less than the size of the equal numbered filter coefficients.

Two input samples give one output samples. The i^{th} outputsample is valid after the coefficient h₁ is multiplied with its corresponding input sample and added with its corresponding value of 1^{st} ringbuffer 120. At this time the signal “enable” is valid.

The system is a realization of an decimation by factor 2 with polyphase FIR filter which is reduced in size, e.g. a realization with as few elements as possible. So the realization on an ASIC is smaller and may be cheaper. Only one multiplier is necessary because of running the filter at a higher clock rate, and the memory size of the sample buffer for the filter convolution is halved.

This structure may also be applied in cases of decimation by factor 4, 8, . . . 2^{x}. In this cases the coefficients have to be reordered and the size of the buffer D₁ shrinks by the decimation factor.

For a decimation by factor 4 the order of the coefficients is
h₀, h₄, . . . , h_{N-4}, h₁, h₅, . . . , h_{N-3}, h₂, h₆, . . . , h_{N}₋₂ , h₃, h₇, . . . , h_{N-1}.

In this case the size of buffer D₁ is equal to N/4.

For a decimation by factor 8 the order of the coefficients is
h₀, h₈, . . . , h_{N-8}, h₁, h₉, . . . , h_{N-7} , h₂, h₁₀, . . . , h_{N-6}, h₃, h₁₁, . . . , h_{N-5}, h₄, h₁₂, . . . , h_{N-4}, h₅, h₁₃, . . . , h_{N-3}, h₆, h₁₄, . . . , h_{N-2}, h₇, h₁₅, . . . , h_{N-1}.

In this case the size of buffer D₁ is equal to N/8.

It should be noted that the above explained filter may also be realized by respective method steps. Such a method may then be executed based on a computer program product including computer program instructions that cause a computer to execute the method.

1. Digital filter, comprising:
a multiplier configured to generate an intermediate signal, wherein said intermediate signal is generated by multiplying an input signal with a filter coefficient signal, wherein said multiplier is operated at a clock rate and said input signal has a sampling rate, wherein said clock rate is higher than said sampling rate;
a first buffer configured to supply said filter coefficient signal to said multiplier at said clock rate, wherein said filter coefficient signal represents N filter coefficients in a periodic order, wherein N denotes the order of said digital filter;
a second buffer configured to buffer N/2 samples of an intermediate output signal and to generate a respective time delayed intermediate output signal; and
an adder configured to generate said intermediate output signal or an output signal of said digital filter based on an addition of said time delayed intermediate output signal and said intermediate signal.

2. Digital filter according to claim 1, wherein said multiplier is the only multiplier of said digital filter.

3. Digital filter according to any of the preceding claims, wherein said first buffer and said second buffer are the only buffers of said digital filter.

4. Digital filter according to any of the preceding claims, wherein said first buffer and/or said second buffer are ring buffers.

5. Digital filter according to any of the preceding claims, wherein said first buffer includes a delay element configured to store said N filter coefficients.

6. Digital filter according to claim 5, wherein said first buffer includes a first switch configured to switch between an initialization position and a runtime position, wherein in said initialization position said filter coefficients are loaded into said delay element, and in said runtime position said filter coefficients are read from said delay element and output via said filter coefficient signal.

7. Digital filter according to any of the preceding claims, wherein said second buffer comprises a second switch configured to set said time delayed intermediate output signal to zero if the (N−1)-th filter coefficient is processed.

8. Digital filter according to any of the preceding claims, wherein said digital filter realizes a transposed finite impulse response (FIR) filter.

9. Digital filter according to any of the preceding claims, comprising a sample-and-hold mechanism configured to receive said intermediate output signal and to sample and hold a sample of said intermediate output signal at a point in time when said intermediate output signal corresponds to a valid sample of said output signal of said digital filter.

10. Digital filter according to any of the preceding claims, wherein said periodic order comprises a first and second sequence of said N filter coefficients, wherein said first sequence includes all even filter coefficients and said second sequence includes all uneven filter coefficients.

11. Digital filter according to claim 10, wherein a one sample of said input signal is multiplied with all filter coefficients of said first sequence and a subsequent sample of said input signal is multiplied with all filter coefficients of said second sequence, wherein one output sample of said output signal is output for said one sample and said subsequent sample.

12. Digital filter according to claim 11, wherein in said first sequence all even filter coefficients are arranged in ascending order and in said second sequence all uneven filter coefficients are arranged in ascending order.

13. Digital filter according to any of the preceding claims, wherein said periodic order is based on the following order of filter coefficients: h₀, h₂, . . . , h_{N-2}, h₁, h₃, . . . , h_{N-1}, wherein hᵢ denotes the i-th filter coefficient.

14. Digital filter according to any of claims 10 to 13, comprising a sample-and-hold mechanism configured to receive said intermediate output signal and to sample and hold a sample of said intermediate output signal at a point in time when the first uneven filter coefficient (h₁) of said second sequence is processed.

15. Digital filter, wherein said clock rate is greater than or equal to N times said sampling rate (N*fₛ).

16. Digital filter according to any of the preceding claims, wherein said output signal has an output sampling rate which is essentially equal to one half of the input sampling rate.

17. Digital filter according to any of claims 1 to 9, wherein said output signal has an output sampling rate which is essentially equal to one fourth of the input sampling rate, and wherein said periodic order is based on the following order of filter coefficients: h₀, h₄, . . . , h_{N-4}, h₁, h₅, . . . , h_{N-3}, h₂, h₆, . . . , h_{N-2}, h₃, h₇, . . . , h_{N-1}, wherein hᵢ denotes the i-th filter coefficient.

18. Digital filter according to claim 17, wherein the size of said second buffer is equal to N/4.

19. Digital filter according to any of claims 1 to 9, wherein said output signal has an output sampling rate which is essentially equal to one eighth of the input sampling rate, and wherein said periodic order is based on the following order of filter coefficients: h₀, h₈, . . . , h_{N-8}, h₁, h₉, . . . , h_{N-7}, h₂, h₁₀, . . . , h_{N-6}, h₃, h ₁₁, . . . , h_{N-5}, h₄, h₁₂, . . . , h_{N-4}, h₅, h₁₃, . . . , h_{N-3}, h₆, h₁₄, . . . , h_{N-2}, h₇, h₁₅, . . . , h_{N-1}, wherein hᵢ denotes the i-th filter coefficient.

20. Digital filter according to claim 19, wherein the size of said second buffer is equal to N/8.

21. Method for filtering an input signal having a sampling rate, comprising:
providing a filter coefficient signal at a clock rate, wherein said filter coefficient signal represents N filter coefficients in a periodic order, wherein N denotes the order of the filtering, and wherein said clock rate is higher than said sampling rate;
multiplying, at said clock rate, said input signal with said filter coefficient signal thereby generating an intermediate signal;
buffering N/2 samples of an intermediate output signal thereby generating a respective time delayed intermediate output signal;
determining said intermediate output signal by adding said time delayed intermediate output signal and said intermediate signal;
determining an output signal based on said intermediate output signal.

22. Method according to claim 21, wherein said step of multiplying is the only multiplying step performed for filtering said input signal.

23. Method according to claim 21 or 22, wherein said time delayed intermediate output signal is set to zero if the (N−1)-th filter coefficient is processed.

24. Method according to any of claims 21 to 23, wherein said filtering realizes a transposed finite impulse response (FIR) filtering.

25. Method according to any of claims 21 to 24, wherein said output signal is determined by sampling-and-holding said intermediate output signal at a point in time when said intermediate output signal corresponds to a valid sample.

26. Method according to any of claims 21 to 25, wherein said periodic order comprises a first and second sequence of said N filter coefficients, wherein said first sequence includes all even filter coefficients and said second sequence includes all uneven filter coefficients.

27. Method according to claim 26, wherein in said first sequence all even filter coefficients are arranged in ascending order and in said second sequence all uneven filter coefficients are arranged in ascending order.

28. Method according to claim 26 or 27, wherein said periodic order is based on the following order of filter coefficients: h₀, h₂, . . . , h_{N-2}, h₁, h₃, . . . , h_{N-1}, wherein hᵢ denotes the i-th filter coefficient.

29. Method according to any of claims 26 to 28, wherein said output signal is determined by sampling-and-holding said intermediate output signal at a point in time when the first uneven filter coefficient (h₁) of said second sequence is processed.

30. Method according to any of claims 21 to 29, wherein said clock rate is greater than or equal to N times said sampling rate (N*fₛ).

31. Method according to any of claims 21 to 30, wherein said output signal has an output sampling rate which is essentially equal to one half of the input sampling rate.

32. Method according to any of claims 21 to 27, wherein said output signal has an output sampling rate which is essentially equal to one fourth of the input sampling rate, and wherein said periodic order is based on the following order of filter coefficients: h₀, h₄, . . . , h_{N-4}, h₁, h₅, . . . , h_{N-3}, h₂, h₆, . . . , h_{N-2}, h₃, h₇, . . . , h_{N-1}, wherein hᵢ denotes the i-th filter coefficient.

33. Method according to any of claims 21 to 27, wherein said output signal has an output sampling rate which is essentially equal to one eighth of the input sampling rate, and wherein said periodic order is based on the following order of filter coefficients: h₀, h₈, . . . , h_{N-8}, h₁, h₉, . . . , h_{N-7}, h₂, h₁₀, . . . , h_{N-6}, h₃, h₁₁, . . . , h_{N-5}, h₄, h₁₂, . . . , h_{N-4}, h₅, h₁₃, . . . , h_{N-3}, h₆, h₁₄, . . . , h_{N-2}, h₇, h₁₅, . . . , h_{N-1}, wherein hᵢ denotes the i-th filter coefficient.

34. Digital filter, comprising:
a first buffer configured to generate a first output signal having a clock rate and representing N filter coefficients in a periodic order;
a multiplier configured to generate an intermediate signal, wherein said intermediate signal is generated by multiplying an input signal with said first output signal, wherein said input signal has a sampling rate that is lower than said clock rate;
a second buffer configured to buffer N/2 samples of an output signal of said digital filter and to generate a respective time delayed output signal; and
an adder configured to generate said output signal based on an addition of said time delayed output signal and said intermediate signal.

35. Method for filtering an input signal, comprising:
providing a first output signal having a clock rate and representing N filter coefficients in a periodic order;
generating an intermediate signal, wherein said intermediate signal is generated by multiplying an input signal with said first output signal, wherein said input signal has a sampling rate that is lower than said clock rate;
buffering N/2 samples of an output signal, wherein a respective time delayed output signal is generated; and
generating said output signal by adding said time delayed output signal and said intermediate signal.

36. A computer program product including computer program instructions that cause a computer to execute a method for filtering an input signal having a sampling rate, comprising:
providing a filter coefficient signal at a clock rate, wherein said filter coefficient signal represents N filter coefficients in a periodic order, wherein N denotes the order of the filtering, and wherein said clock rate is higher than said sampling rate;
multiplying, at said clock rate, said input signal with said filter coefficient signal thereby generating an intermediate signal;
buffering N/2 samples of an intermediate output signal thereby generating a respective time delayed intermediate output signal;
determining said intermediate output signal by adding said time delayed intermediate output signal and said intermediate signal;
determining an output signal based on said intermediate output signal.
